(19) United States
(12) Patent Application Publication
(10) Pub. No.: US 2003/0198754 A1
(43) Pub. Date: Oct. 23, 2003

(54) Aluminum oxide chamber and process

(76) Inventors: Ming Xi, Palo Alto, CA (US); Alfred Mak, Union City, CA (US); Joseph Yudovsky, Campbell, CA (US); Salvador P. Umotoy, Antioch, CA (US); David Santi, San Mateo, CA (US)

Correspondence Address: Patent Counsel, APPLIED MATERIALS, INC., P.O. Box 450A, Santa Clara, CA, 95052, US

(21) Appl. No.: 10/302,773

(22) Filed: Nov. 21, 2002

Related U.S. Application Data
(63) Continuation-in-part of application No. 10/016,300, filed on Dec. 12, 2001.
(60) Provisional application No. 60/357,382, filed on Feb. 15, 2002.
(60) Provisional application No. 60/305,970, filed on Jul. 16, 2001.

(51) Int. Cl. C23C 16/00; C23F 1/00; H01L 21/306

(52) U.S. Cl. 427/576; 118/715; 156/345.33

(57) ABSTRACT

Embodiments of this invention relate to a processing chamber and methods of distributing reactants therein to facilitate cyclical layer deposition of films on a substrate. One embodiment of a substrate processing chamber includes a chamber body and a substrate support disposed in the chamber body. A lid is disposed on the chamber body. An injection plate having a recess is mounted on the lid. A bottom surface of the recess has a plurality of apertures limited to an area proximate a central portion of the substrate receiving surface of the substrate support. Another embodiment of a substrate processing chamber includes a chamber body having interior sidewalls and an interior bottom wall. A top liner is disposed along the interior sidewalls of the chamber body. A bottom liner is disposed on the interior bottom wall of the chamber body. A gap is defined between the top liner and the bottom liner to allow a purge gas to be introduced therethrough. Still another embodiment of a substrate processing chamber includes a chamber body and a lid assembly defining an interior cavity. Two or more exhausts are selectively coupled to the interior cavity.

### RELATED APPLICATIONS

This application claims benefit of U.S. Provisional Patent 60/357,382, filed Feb. 15, 2002, and is a continuation-in-part of U.S. patent application Ser. No. 10/016,300, filed Dec. 12, 2001, which claims priority to U.S. Provisional Application No. 60/305,970, filed Jul. 16, 2001.

Additionally, this application is related to U.S. patent application Ser. No. 09/798,251, entitled “Lid Assembly for a Processing System to Facilitate Sequential Deposition Techniques” filed on Mar. 2, 2001; U.S. patent application Ser. No. 09/798,258, entitled “Processing Chamber and Method of Distributing Process Fluids Therein to Facilitate Sequential Deposition of Films” filed on Mar. 2, 2001; U.S. patent application Ser. No. 09/605,593, entitled “Bifurcated Deposition Process For Depositing Refractory Metal Layer Employing Atomic Layer Deposition And Chemical Vapor Deposition” filed on Jun. 28, 2000; and U.S. patent application Ser. No. 09/678,266, entitled “Methods and Apparatus For Depositing Refractory Metal Layers Employing Sequential Deposition Techniques To Form Nucleation Layers” filed on Oct. 3, 2000, all of which are incorporated herein by reference in their entireties.

### BACKGROUND OF THE INVENTION

1. Field of the Invention

Embodiments of this invention relate to semiconductor processing. More particularly, embodiments of this invention relate to a processing chamber and methods of distributing reactants therein to facilitate cyclical layer deposition of films on a substrate.

2. Description of the Related Art

As circuit devices have continued to diminish, there is a need to deposit conformal, thin layers of material. Atomic layer deposition (ALD) techniques and other cyclical deposition techniques have demonstrated superior step coverage of deposited layers on a substrate surface. However, there are many challenges associated with cyclical deposition techniques that greatly affect the cost of operation and ownership. For example, the rate of deposition is typically slower than conventional bulk deposition techniques. As another example, there is a greater likelihood of contamination and premature/unwanted deposition due to the highly reactive precursor species used for deposition. There is a need, therefore, for new methods of cyclical deposition having increased deposition rates and reduced likelihood of contamination and unwanted deposition.

### SUMMARY OF THE INVENTION

One embodiment of a substrate processing chamber includes a chamber body and a substrate support disposed in the chamber body. A lid is disposed on the chamber body. An injection plate having a recess is mounted on the lid. A bottom surface of the recess has a plurality of apertures limited to an area proximate a central portion of the substrate receiving surface of the substrate support.

Another embodiment of a substrate processing chamber includes a chamber body having interior sidewalls and an interior bottom wall. A top liner is disposed along the interior sidewalls of the chamber body. A bottom liner is disposed on the interior bottom wall of the chamber body. A gap is defined between the top liner and the bottom liner to allow a purge gas to be introduced therethrough.

Still another embodiment of a substrate processing chamber includes a chamber body and a lid assembly defining an interior cavity. Two or more exhausts are selectively coupled to the interior cavity.

One embodiment of a method for forming aluminum oxide over a substrate includes providing one or more cycles of compounds to a region adjacent a substrate surface. Each cycle includes separately providing a pulse of an aluminum precursor and a pulse of an oxidizing agent to a region adjacent a substrate surface. Each cycle further includes providing a purge gas to the region adjacent the substrate surface between the pulse of the aluminum precursor and the pulse of the oxidizing agent.

### BRIEF DESCRIPTION OF THE DRAWINGS

A more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one exemplary embodiment of a processing chamber.

FIG. 2 is a schematic top perspective view and FIG. 3 is a schematic cross-sectional view of one embodiment of an injection plate.

FIG. 4 is a schematic top perspective view and FIG. 5 is a schematic cross-sectional view of another embodiment of an injection plate.

FIG. 6 is a schematic perspective assembly view of a top liner and a bottom liner.

FIG. 7 is a schematic perspective view of one embodiment of the processing chamber.

FIG. 8 is a schematic partial perspective view of one embodiment of a lid assembly and a process fluid injection assembly.

FIG. 9 is a schematic diagram illustrating the components of an aluminum oxide deposition system in accordance with an embodiment of the present invention.

FIG. 10 is a schematic top plan view of an integrated processing system configured to form a film stack having an aluminum oxide layer in accordance with embodiments of the present invention.

FIG. 11 is a flow chart depicting various embodiments of a method for depositing an aluminum oxide layer by cyclical layer deposition onto a substrate in a processing chamber.

FIG. 12 is a flow chart depicting various embodiments of a method for annealing sequences performed at various times during the aluminum oxide deposition cycle in a processing chamber.

FIG. 13 is a flow diagram depicting various embodiments of a method for additional oxidizing sequences which may be performed at various times during the aluminum oxide deposition cycle in a processing chamber.

FIG. 14 is a flow diagram depicting an integrated deposition sequence of a controllable, variable dielectric constant laminate.

FIG. 15 is a flow diagram depicting another embodiment of an integrated sequence to form a controllable, variable dielectric constant laminate.

FIG. 16 is a flow diagram depicting one example of an integrated process sequence for depositing dielectric and conductive materials.

FIG. 17 is a diagram depicting one example of the control signals for delivering compounds in an aluminum oxide cyclical layer deposition method utilizing a process chamber having a dual exhaust system.

FIG. 18 is a diagram depicting one example of the control signals for delivering compounds in an aluminum oxide cyclical layer deposition method utilizing a process chamber having a dual exhaust system and a diverter.

FIG. 19 is a flow chart depicting various embodiments of a deposition of aluminum oxide (AlₓO_{y}) using controllable/variable hydrogen/oxygen content water vapor.

FIG. 20 is a schematic cross-section view of an example of a processing chamber having a remote plasma showerhead.

To facilitate understanding, identical reference numerals have been used, wherever possible, to designate identical elements that are common to the figures.

### DETAILED DESCRIPTION OF THE INVENTION

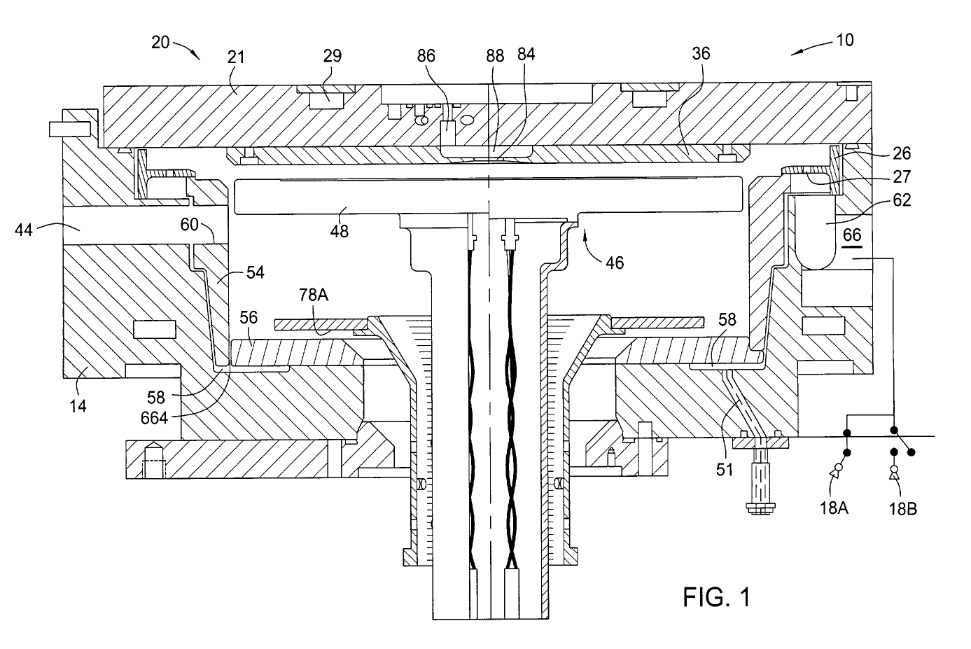

FIG. 1 is a schematic cross-sectional view of one exemplary embodiment of a processing chamber 10 that may be used to deposit aluminum oxide by cyclical deposition techniques in accordance with aspects of the present invention. The term “cyclical deposition” as used herein refers to the sequential introduction of reactants to deposit a thin layer over a structure and includes processing techniques such as atomic layer deposition and rapid sequential chemical vapor deposition. Reactants can be precursors, reducing agents, oxidizing agents, catalysts, atomic species, other compounds, and mixtures thereof. The sequential introduction of reactants may be repeated to deposit a plurality of thin layers to form a conformal layer to a desired thickness. More than one of the reactants may be present in the chamber at the same time during the sequential introduction of reactants. Alternatively, only one of the reactants may be present in the chamber at one time during the sequential introduction of reactants. The present invention also includes depositing aluminum oxide by cyclical deposition techniques utilizing other processing systems.

The processing chamber 10 includes a chamber body 14 and a lid assembly 20. The chamber body 14 includes a slit valve opening 44 to allow transfer of a substrate to and from the processing chamber 10. Disposed within the processing chamber 10 is a heater/lift assembly 46 that includes a substrate support pedestal 48. The heater/lift assembly 46 may be moved vertically within the chamber 10 so that a distance between the support pedestal 48 and the lid assembly 20 may be controlled. The support pedestal 48 may include an embedded heater element, such as a resistive heater element or heat transfer fluid, utilized to control the temperature thereof. Optionally, a substrate disposed on the support pedestal 48 may be heated using radiant heat. The support pedestal 48 may also be configured to hold a substrate thereon, such as by a vacuum chuck, by an electrostatic chuck, or by a clamp ring.

The lid assembly 20 includes a lid 21 and an injection plate 36. The injection plate 36 is generally annular and includes a side facing the lid 21 and another side generally facing the support pedestal 48. The lid 21 includes one or more inlet passages 86 disposed therethrough to allow delivery of reactive (i.e. precursor, reductant, oxidant), carrier, purge, cleaning and/or other fluids through the lid 21 and into the processing chamber 10. Fluids enter a plenum or region 88 defined between the lid 21 and the injection plate 36 before entering the processing chamber 10. The injection plate 36 may include a mixing lip 84 to re-direct gases toward the center of the plenum 88 and into the process chamber 10. The injection plate 36 is utilized to prevent gases delivered into the chamber 10 from blowing off gases adsorbed onto the surface of the substrate. The injection plate 36 may be removed from the lid 21 for cleaning and/or replacement. Alternatively, the injection plate 36 and lid 21 may be fabricated as a single member.

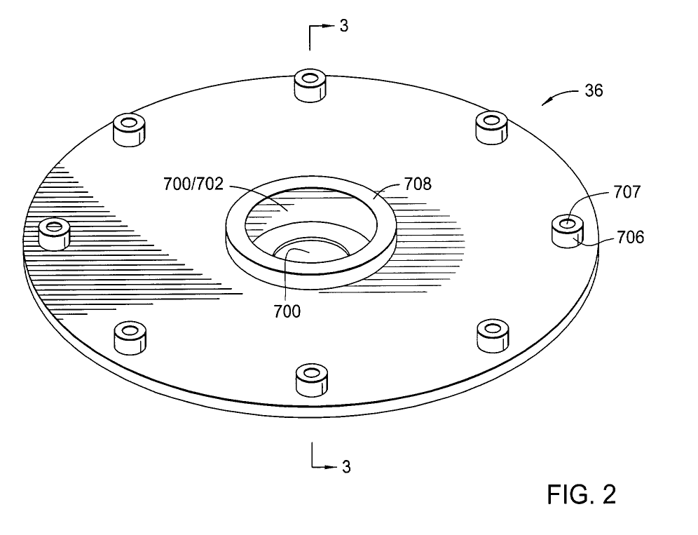

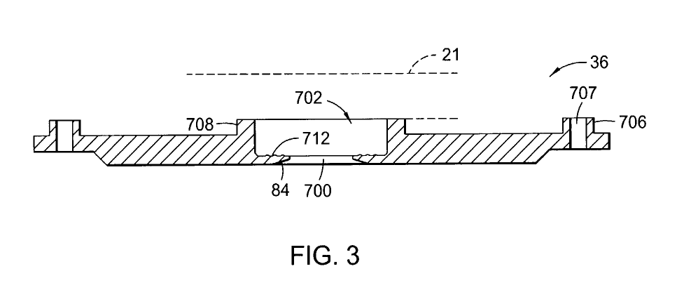

FIG. 2 is a schematic top perspective view and FIG. 3 is a schematic cross-sectional view of the injection plate 36 of FIG. 1. The injection plate 36 has a passage 700 formed therethrough. A recess 702, typically concentric with the passage 700, and the lid 21 define the plenum 88 (FIG. 1) therebetween. The recess 702, typically circular in form, is configured to extend radially from a centerline of the injection plate 36 to a diameter that extends to or beyond the one or more inlet passages 86 (FIG. 1) disposed through the lid 21 so that gases flowing from the inlet passages 86 enter the recess 702 and exit through the passage 700.

A bottom 712 of the recess 702 defines the mixing lip 84 that extends radially inward to the passage 700. Gases flowing into the recess 702 from the inlet passages 86 are re-directed by the surface of the mixing lip 84 generally towards the center of the recess 702 before passing through the passage 700 and into the process chamber 10. The recess 702 combined with a singular exit passage for delivering gases to the chamber 10 (e.g., the passage 700) advantageously reduces the surface area and orifices requiring purging and cleaning over conventional showerheads having multiple orifices for gas delivery.

The side of the injection plate 36 facing the lid 21 may include features for reducing the contact area between the injection plate 36 and the lid 21. Providing reduced contact area allows the injection plate 36 to be operated at a higher temperature than the lid 21, which in some processes enhances deposition performance. As shown in FIGS. 2 and 3, the side of the injection plate 36 facing the lid 21 may include a plurality of bosses 706, each having a mounting hole 707 passing therethrough. The bosses 706 allow the injection plate 36 to be coupled to the lid 21 by fasteners passing through the mounting holes 707 into holes formed in the lid 21. Additionally, a ring 708 projects from the side of the injection plate 36 facing the lid 21 and circumscribes the recess 702. The ring 708 and bosses 706 project to a common elevation that allows the injection plate 36 to be coupled to the lid 21 in a spaced-apart relation. The spaced-apart relation and the controlled contact area permit a controlled thermal transfer between the injection plate 36 and the lid 21. Accordingly, the contact area provided by bosses 706 and the ring 708 may be designed to tailor the amount and location of the solid-to-solid contact area available for thermal transfer between the injection plate 36 and the lid 21 as a particular deposition process requires.

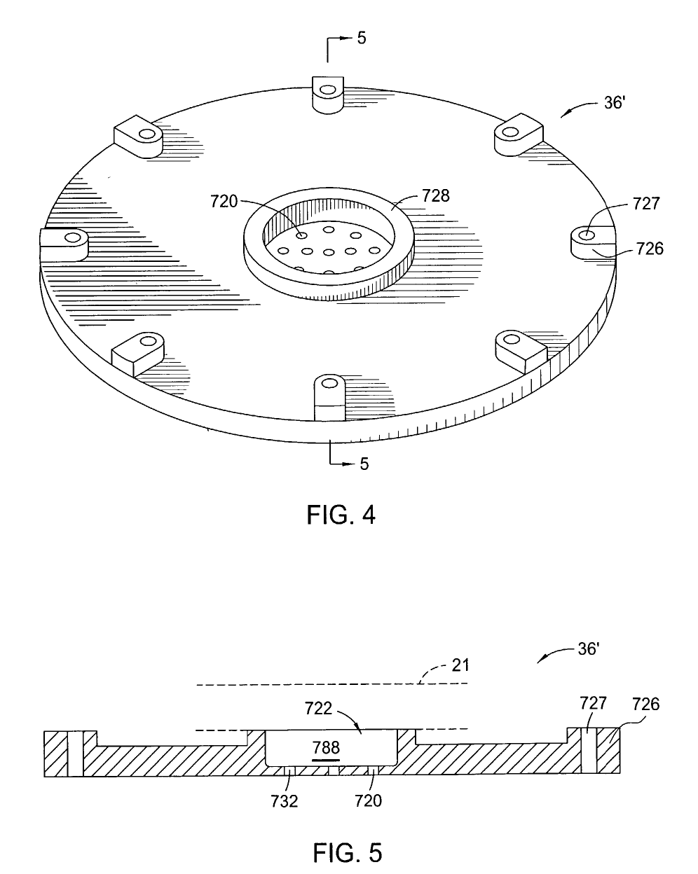

FIG. 4 is a schematic top perspective view and FIG. 5 is a schematic cross-sectional view of another embodiment of an injection plate 36′. A recess 722 and the lid 21 define a plenum 788 therebetween. A bottom 732 of the recess 722 defines a surface have a plurality of apertures 720. The apertures 720 are formed in the injection plate 36 so that when the injection plate 36 is disposed above a substrate support the apertures 720 are proximate a central portion of the substrate receiving surface of the substrate support. The recess 722, typically circular in form, is configured to extend radially from a centerline of the injection plate 36 to a diameter that extends to or beyond the one or more inlet passages 86 (FIG. 1) disposed through the lid 21 so that gases flowing from the inlet passages 86 enter the recess 722 and exit through the apertures 720. Gases flowing into the recess 722 from the inlet passages 86 are re-directed by the surface of the bottom 732 of the recess 722, and then, pass through apertures 720 and into the process chamber 10. In one aspect, the apertures 720 provide gases proximate a central portion of the substrate support which reduces the surface area requiring purging and cleaning over conventional showerheads having multiple orifices positioned above substantially the entire surface of the substrate receiving surface of a substrate support.

The side of the injection plate 36′ facing the lid 21 may include features for reducing the contact area between the injection plate 36′ and the lid 21. Providing reduced contact area allows the injection plate 36′ to be operated at a higher temperature than the lid 21, which in some processes enhances deposition performance. As shown in FIGS. 4 and 5, the side of the injection plate 36′ facing the lid 21 may include a plurality of bosses 726, each having a mounting hole 727 passing therethrough. The bosses 726 allow the injection plate 36 to be coupled to the lid 21 by fasteners passing through the mounting holes 727 into holes formed in the lid 21. Additionally, a ring 728 projects from the side of the injection plate 36′ facing the lid 21 and circumscribes the recess 722. The ring 728 and bosses 726 project to a common elevation that allows the injection plate 36′ to be coupled to the lid 21 in a spaced-apart relation. The spaced-apart relation and the controlled contact area permit a controlled thermal transfer between the injection plate 36′ and the lid 21. Accordingly, the contact area provided by bosses 726 and the ring 728 may be designed to tailor the amount and location of the solid-to-solid contact area available for thermal transfer between the injection plate 36′ and the lid 21 as a particular deposition process requires.

Referring to FIG. 1, the lid 21 may further comprise one or more temperature fluid control channels 29 to control the temperature of the lid assembly 20 by providing a cooling fluid or a heating fluid to the lid 21 depending on the particular process being performed in the chamber 10. Controlling the temperature of the lid assembly 20 may be used to prevent gas decomposition, deposition, or condensation thereon.

Disposed along the sidewalls of the chamber body 14 proximate the lid assembly 20 is a mouth of a pumping channel 62. The pumping channel 62 is coupled by a conduit 66 to a pump system 18 which controls the pressure of the processing chamber 10. A pumping plate 26 may be optionally disposed over the mouth of the pumping channel 62. The pumping plate 26 includes a plurality of apertures 27 formed therethrough to control the flow of fluids from the processing chamber 10 into the pumping channel 62. In other embodiments, the pumping plate 26 may be removed to increase conductance into the pumping channel 62.

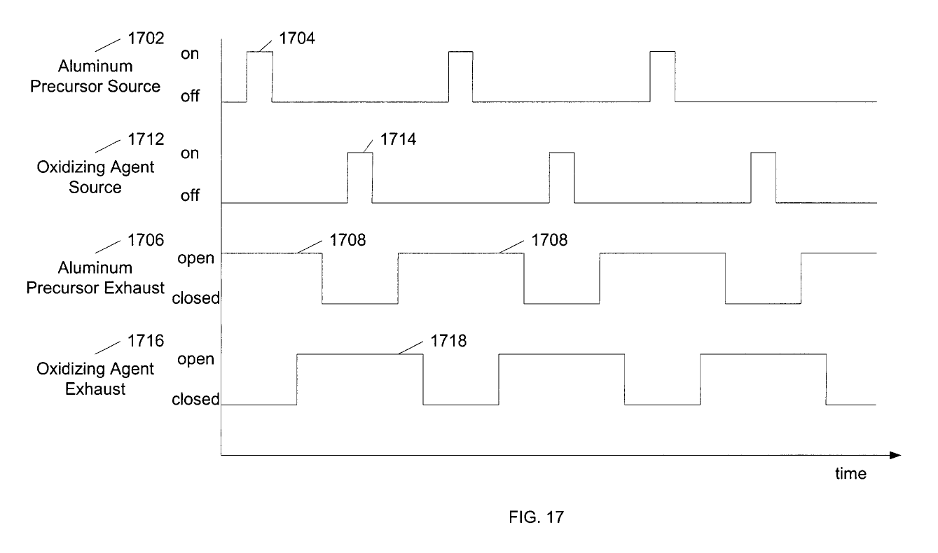

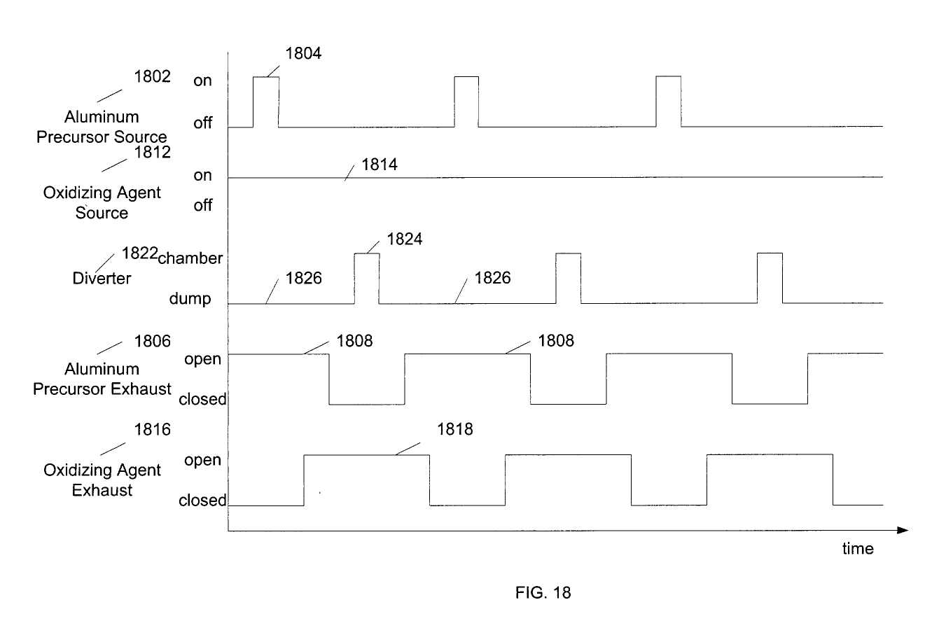

In the figure, the pump system 18 comprises a dual exhaust system having a first exhaust 18A and a second exhaust 18B. Each exhaust may be selectively coupled to the interior cavity of the chamber body 14. For example, at any given moment, either one, both, or none of the exhausts 18A, 18B are open to the interior cavity of the chamber. The dual exhaust system is described in greater detail below in reference to FIGS. 17 and 18.

Still referring to FIG. 1, a liner assembly is disposed in the processing chamber 10 and includes a top liner 54 and a bottom liner 56. The top liner 54 and the bottom liner 56 may be formed from quartz or any suitable material such as aluminum, stainless steal, graphite, silicon carbide, ceramics, aluminum oxide, aluminum nitride, and other suitable materials. The top liner 54 surrounds the support pedestal 48 and includes an aperture 60 that aligns with the slit valve opening 44 disposed on a sidewall of the chamber body 14.

The bottom liner 56 extends transversely to the top liner 54 and is disposed against a bottom of the chamber body 14 disposed opposite to the lid assembly 20. A chamber channel 58 is defined between the chamber body 14 and the bottom liner 56. A purge gas is introduced from a purge gas inlet 51 into the chamber channel 58 and flows through gap 664 between the bottom liner 56 and the top liner 54. The purge gas flows between the top liner 56 and the substrate support pedestal 48 to confine process gases in a volume between the substrate support pedestal 48 and the lid assembly 20. As a consequence, pulse times of precursors gases and purging of this volume for a particular process may be reduced.

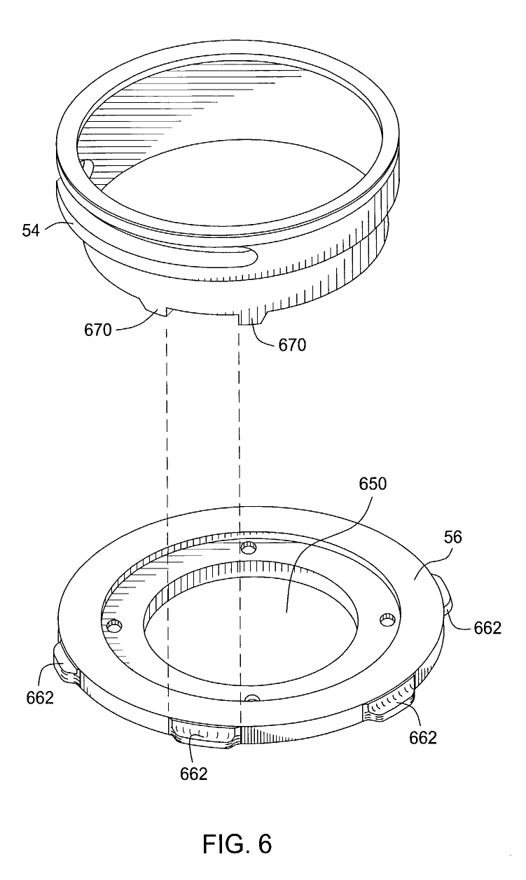

FIG. 6 is a schematic perspective assembly view of the top liner 54 and the bottom liner 56. The bottom liner 56 includes an orifice 650 to allow lift ring 78a (FIG. 1) and the stem of the 46 heater/lift assembly (FIG. 1) to be disposed therethrough. The bottom liner further includes a plurality of ledges 662 for supporting the top liner 54. The top liner 54 rests on the ledges 662 so that a there is a gap 664 (FIG. 1) between the top liner 54 and the bottom liner 56 for the flow of a purge gas therethrough from the chamber channel 58. The top liner 54 has a pair of extending fingers 670 which align around one of the ledges 662 for alignment of the top liner 54 within the processing chamber 10.

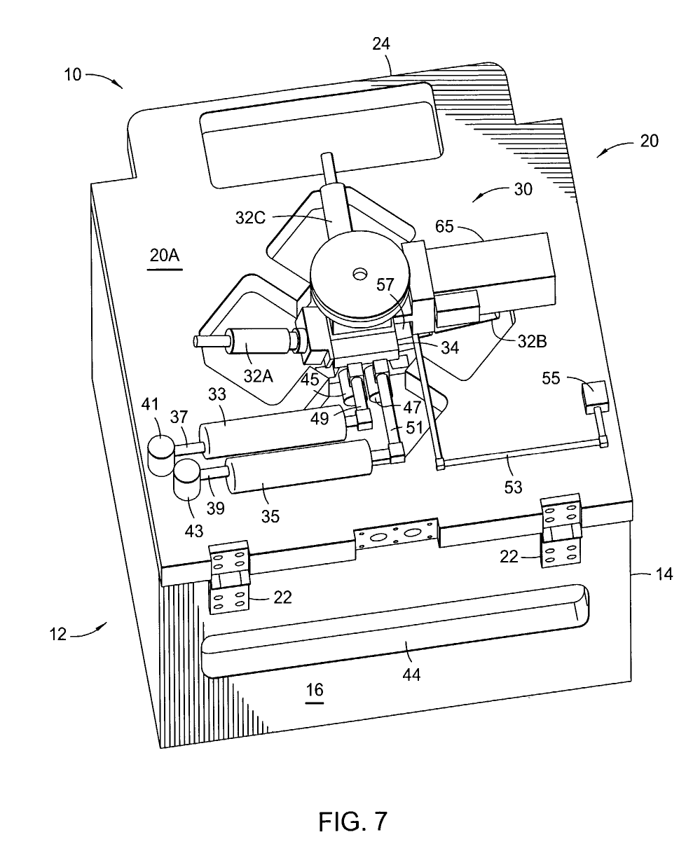

FIG. 7 is a schematic perspective view of one embodiment of the processing chamber 10. The lid assembly 20 is pivotally coupled to the chamber body 14 via hinges 22. A handle 24 is attached to the lid assembly 20 opposite the hinges 22. The handle 24 facilitates moving the lid assembly 20 between opened and closed positions. In the opened position, the interior of the chamber body 14 is exposed. In the closed position shown in FIG. 1, the vacuum lid assembly 20 covers the chamber body 14 forming a fluid-tight seal therewith. In this manner, a vacuum formed in the processing chamber 10 is maintained as the lid assembly 20 seals against the chamber body 14.

A process fluid injection assembly 30 is mounted to the lid assembly 20 to deliver reactive, carrier, purge, cleaning and/or other fluids into the processing chamber 10. The fluid injection assembly 30 includes a gas manifold 34 mounting a plurality of control valves, 32a, 32b and 32c. The valves 32a, 32b and 32c provide rapid and precise gas flow with valve open and close cycles of less than about one second, e.g., less than about 0.1 second. In one embodiment, the valves 32a, 32b and 32c are surface mounted, electronically actuated valves. One valve that may be utilized is available from Fujikin of Japan as part number FR-21-6.35 UGF-APD. In another embodiment, the valves 32a, 32b, and 32c are surface mounted, pneumatically actuated valves. Other valves that operate at substantially the same speed and precision may also be used. In one embodiment, an aluminum-containing compound, such as trimethyl aluminum Al(CH₃)₃, is connected to valve 32a and an oxidizing compound, such as ozone O₃, is connected to valve 32c.

The lid assembly 20 may further optionally include one or more (two are shown in FIG. 7) gas reservoirs 33, 35 that are fluidly connected between one or more process gas sources and the gas manifold 34. The gas reservoirs 33, 35 provide bulk gas delivery proximate to each of the valves 32a, 32b, 32c. The reservoirs 33,35 are sized to insure that an adequate gas volume is available proximate to the valves 32a, 32b, 32c during each cycle of the valves 32a, 32b and 32c during processing to minimize the time required for fluid delivery, thereby shortening sequential deposition cycles. For example, the reservoirs 33, 35 may be about 5 times the volume required in each gas delivery cycle.

Gas lines 37, 39 extend between the connectors 41, 43 and the reservoirs 33, 35 respectively. The connectors 41, 43 are coupled to the lid 21. The process gases are typically delivered through the chamber body 14 through the lid assembly 20, and to the process fluid injection assembly 30.

To maximize the throughput, the lid assembly 20 and the injection assembly 30 are configured to minimize the time required to inject process fluids into the processing chamber 10 and disperse the fluids over the process region proximate to the support pedestal 48. For example, the proximity of the reservoirs 33, 35 and valves 32a-b to the gas manifold 34 reduce the response times of fluid delivery, thereby enhancing the frequency of pulses utilized in ALD deposition processes.

Additional connectors 45, 47 are mounted adjacent the gas manifold 34 down stream from the reservoirs 33, 35 and connect to the reservoirs 33, 35 by gas lines 49, 51. The connectors 45, 47 and gas lines 49, 51 generally provide a flowpath for process gases from the reservoirs 33, 35 to the gas manifold 34. A purge gas line 53 is similarly connected between a connector 55 and a connection 57 on the gas manifold 34.

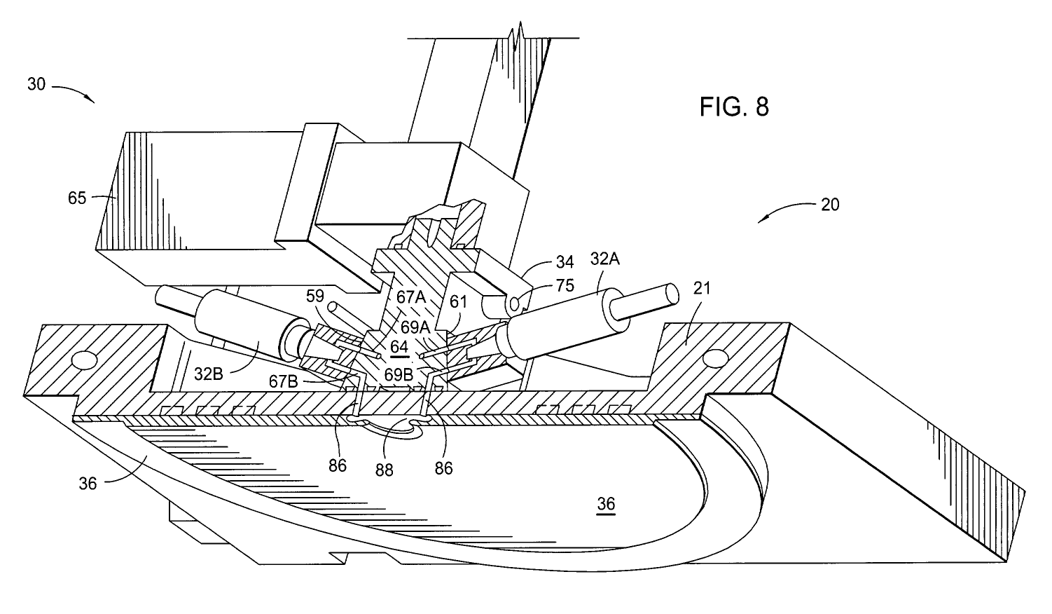

FIG. 8 is a schematic partial perspective view of the lid assembly 20 and the process fluid injection assembly 30. The gas manifold 34 includes a body defining a plurality of mounting surfaces 59, 61, 64. Each valve 32 is fluidly coupled to a separate set of gas channels of the gas manifold 34. Valve 32a is coupled to gas channels 69a, 69b. Valve 32b is coupled to gas channels 67a, 67b. Gas channels 69a, 67a provides passage of gases through the gas manifold 34 to the respective valves 32a, 32b. Gas channels 69b, 67b delivers gases from the respective valves 32a, 32b through the gas manifold 34 and into a respective inlet passage 86 disposed through the lid 21, through the plenum 88, and into the processing chamber. The gas manifold 34 and the valves 32 may be optionally heated to control the temperature of gases flowing therethrough.

The fluid injection assembly 30 may further include an oxidizing agent delivery device 65. The oxidizing agent delivery device 65 may be coupled to a valve 32 or reservoir of the fluid injection assembly 30 or may be coupled to a gas channel through the gas manifold 34. The oxidizing agent delivery device 65 may be an ozonator if ozone processing is desired or a remote activation device if other oxidizing gases are desired. Exemplary ozonators are available from Applied Science and Technology, Inc., of Woburn, Mass.

In another embodiment, oxidizing agent delivery device 65 may be a remote activation source, such as a remote plasma generator, used to generate a plasma of reactive species which can be delivered into the chamber 10. The plasma of reactive species may be generated by applying an electric field to a compound within the remote activation source. The reactive species are then introduced into the chamber 10 via the lid assembly 20. Any power source that is capable of activating the intended compounds may be used. For example, power sources using DC, radio frequency (e), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

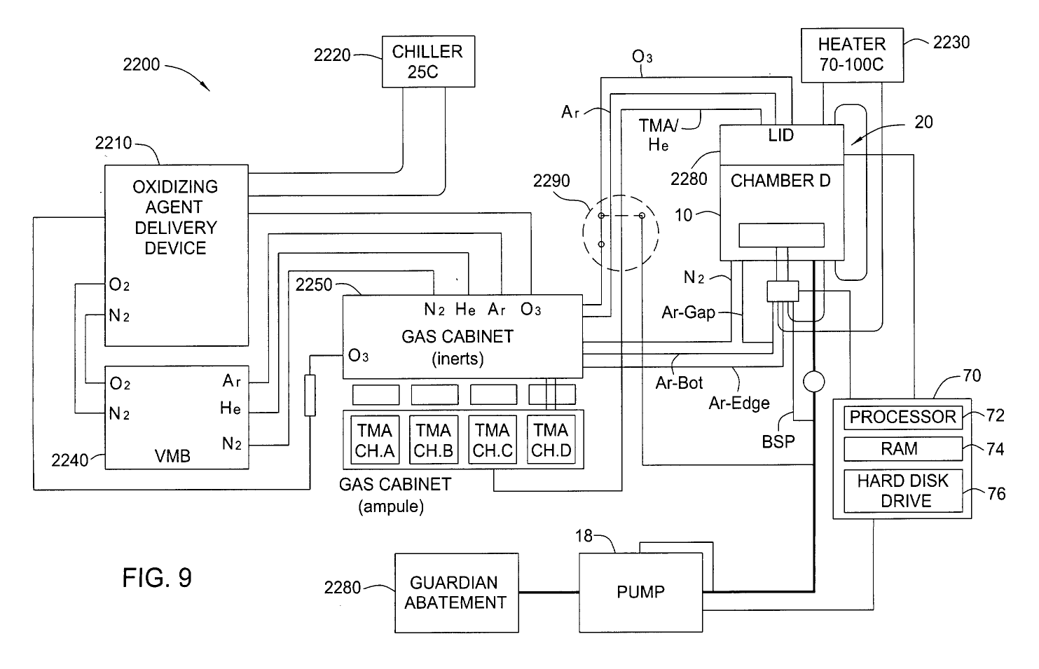

In the embodiment shown in FIG. 8, the oxidizing agent delivery device 65 is mounted on an upper surface of the lid assembly 20 so that the reactive oxidizing agent may be delivered in a minimized conductance pathway. It is believed that mounting the oxidizing agent delivery device 65 on the lid assembly provides an oxidizing agent, such as ozone or oxygen species, at a higher concentration and reactivity than delivering oxidizing agents using conventional techniques and methods. In other embodiments, the oxidizing agent delivery device 65 may be situated apart from the lid assembly 20 but in close proximity to the processing chamber 10 so that a minimized or low conductance pathway is created to improve delivery of the oxidizing agent. In another embodiment, the oxidizing agent delivery device 65 may be located in the pump alley and plumbed to the gas cabinet 2250 (shown in FIG. 9).

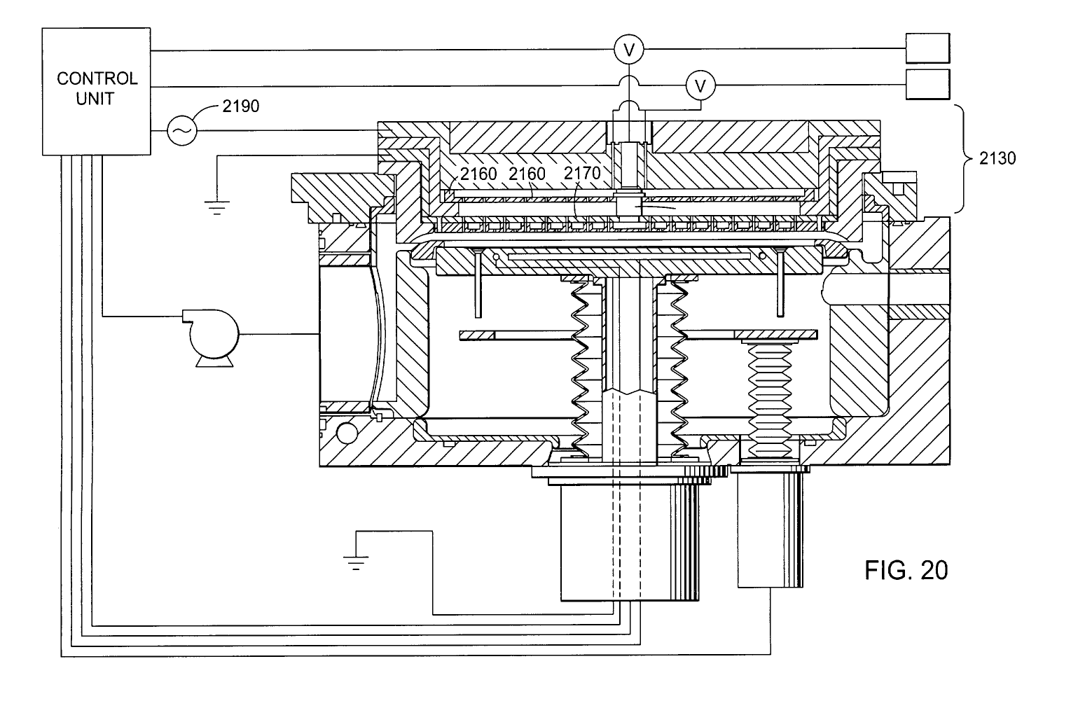

In other embodiments, a remote plasma showerhead may be used to generate a plasma. One example of a remote plasma showerhead is disclosed in U.S. patent application Ser. No. 10/197,940 filed Jul. 16, 2002, which claims priority to U.S. Provisional Patent Application Serial No. 60/352,191 filed Jan. 26, 2002, both of which are incorporated by reference to the extent not inconsistent with the present disclosure. FIG. 20 is a schematic cross-section view of an example of a processing chamber having a remote plasma showerhead 2130. The remote plasma showerhead 2030 comprises a top shower plate 2160 and a bottom shower plate 2170. A power source 2190 is coupled to the top shower plate 160 to provide a power electrode and the bottom shower plate 2170 is grounded to provide a ground electrode. The power source 2190 may be an RF or DC power source. An electric field may be established between the top shower plate 2160 and the bottom shower plate 2170 to generate a plasma from the gases introduced between the top shower plate 2160 and the bottom shower plate 2170.

FIG. 9 is a schematic diagram illustrating the components of an aluminum oxide deposition system 2200 in accordance with an embodiment of the present invention. The aluminum oxide deposition system 2200 includes an oxidizing agent delivery device 2210 coupled to a gas source 2240 and/or to a gas cabinet 2250 to provide one or more oxidizing agents thereto. A chiller 2220 may be coupled to the oxidizing agent delivery device 2210 to cool the oxidizing agent delivery device 2210. The gas source 2240 is coupled to the gas cabinet 2250 which in turn is coupled to a processing chamber 10 to provide a plurality of gases thereto. A heater 2230 may be coupled to a lid assembly 20 of the processing chamber 10 to heat the lid assembly 20. A pump system 18 is coupled to the processing chamber 10 to provide a vacuum to the processing chamber 10. A control system 70 may be coupled to the components of the system 2200 to provide control signals thereto.

The oxidizing agent delivery device 2210 may deliver gases, such as, O₂ and N₂, to the gas source 2240. The oxidizing agent delivery device 2210 is also connected to the gas cabinet 2250 to directly deliver an oxidizing agent, e.g., O₃ or oxygen radicals, to the gas cabinet 2250. The gas source 2240, which delivers gases, such as, argon, helium and nitrogen, is connected to the gas cabinet 2250. The gas cabinet 2250 also includes an ampoule containing a liquid aluminum precursor and a vapor injection system. The ampoule, the line delivering the precursor to the vaporizer, the vaporizer, and the line carrying the vaporized precursor to the chamber can each be heated using conventional methods of heating to reduce the viscosity of the metal-containing compound; to assist in the vaporization of the liquid material prior to injection into the lid assembly 20; and to ensure that the vaporized aluminum precursor does not condense. The heating system is controllable to maintain the lines in a temperature range-determined by the particular aluminum precursor used so that the vapor does not condense nor is it heated to such a temperature that the precursor begins to decompose. Alternatively, the metal-containing compound may be pre-mixed with a solvent to reduce its viscosity and then vaporized prior to flow into the injection valves leading into the chamber. A carrier gas, such as argon, helium, hydrogen, nitrogen, and combinations/mixtures thereof, may be used within the vapor injection system to help facilitate the flow of the metal-containing compound into the lid assembly 20.

A controller 70 regulates the operations of the various components of system 2200. The controller 70 includes a processor 72 in data communication with memory, such as random access memory 74 and a hard disk drive 76 and is in communication with at least the pump system 18 (FIG. 1) and the valves 32a, 32b and 32c (FIG. 7).

The system 2200 may further include a diverter 2290 coupled between the gas cabinet 2250 and the chamber 10. The diverter is selectively movable between a first position and a second position. In the first position, the diverter 2290 directs a gas or gases from the gas cabinet 2250 to the chamber 10. In the second position, the diverter 2290 directs a gas or gas mixture from the gas cabinet 2250 to the foreline of the pump system 18. In one aspect, the diverter 2290 helps reduce the pressure variations of the pump system 18. As shown in the figure, the diverter is coupled to the oxidizing agent line. In other embodiments, the diverter may be coupled to other reactant lines. The diverter 2290 is discussed in more detail in reference to FIG. 18.

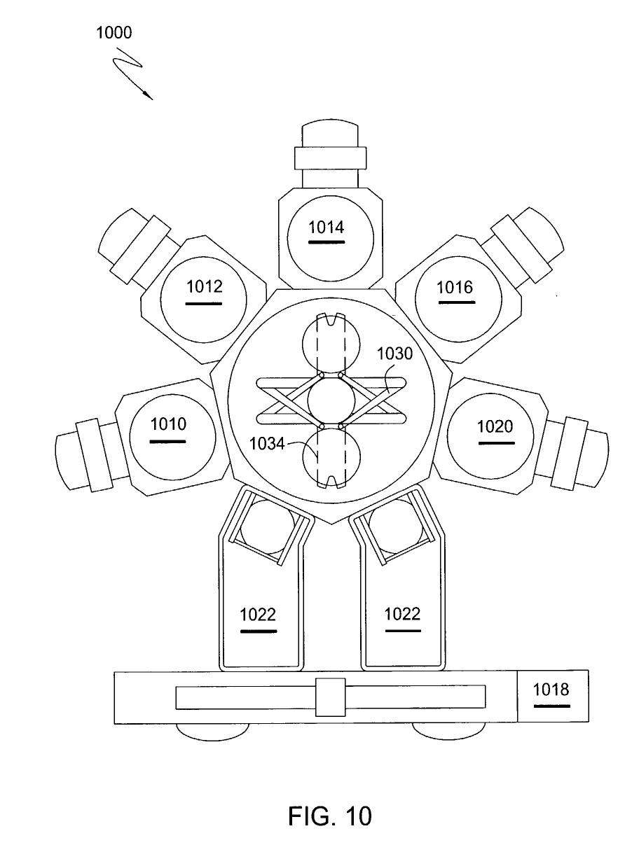

FIG. 10 is a schematic top plan view of an integrated processing system 1000 configured to form a film stack having an aluminum oxide layer in accordance with embodiments of the present invention. The apparatus is a Centura® system and is commercially available from Applied Materials, Inc. of Santa Clara, Calif. The particular embodiment of the system 1000 is provided to illustrate the invention and should not be used to limit the scope of the invention unless otherwise set forth in the claims.

The system 1000 generally includes load lock chambers 1022 for the transfer of substrates into and out from the system 1000. Typically, since the system 1000 is under vacuum, the load lock chambers 1022 may “pump down” the substrates introduced into the system 1000. A robot 1030 having a blade 1034 may transfer the substrates between the load lock chambers 1022 and processing chambers 1010, 1012, 1014, 1016, 1020. Any of the processing chambers 1010, 1012, 1014, 1016, 1020 may be removed from the system 1000 if not necessary for the particular process to be performed by the system 1000. Optionally, a factory interface may be connected on the front end of the system 1000 and may include one or more metrology chambers 1018 connected thereto.

One or more of the chambers 1010, 1012, 1014, 1016, 1020 is an aluminum oxide chamber, such as a processing chamber 10 described above in reference to FIGS. 1-9. Optionally, one or more of the chambers 1010, 1012, 1014, 1016, 1020 may be adapted to deposit a dielectric material, a conductive material, or another material. Optionally, one or more of the chambers 1010, 1012, 1014, 1016, 1020 may be a cleaning chamber, such as a conventional dry chemistry cleaning chamber. Cleaning chambers are used to remove any unwanted products on a substrate following previous processes and prior to additional processing. Examples of a conventional dry chemistry chamber include a Preclean II chamber available from Applied Materials, Inc. of Santa Clara, Calif. Exemplary dry chemistry systems include, but are not limited to, dry plasma systems having controlled environments therein. Suitable dry clean processes include plasma processes of reactive chemistries, such as, fluorine, oxygen, hydrogen, and any combination of inert gases, such as, argon or other sputtering gases. The dry cleaning chambers may generate the plasma in situ or in a remote plasma source connected thereto. Optionally, one or more of the chambers 1010, 1012, 1014,1016,1020 may be an anneal chamber or other thermal processing chamber, such as a Radiance Centura chamber available from Applied Materials, Inc. of Santa Clara, Calif. The system 1000 may also include other types of processing chambers.

One example of a possible configuration of the integrated processing system 1000 includes a load lock chamber 1022 adapted to provide de-gas or pre-heat the substrate, an aluminum oxide cyclical deposition chamber 1010, a second dielectric deposition chamber 1012, a metal deposition chamber 1014, a third dielectric deposition chamber 1016, and an anneal chamber 1020. The substrate passes through the various processing chamber to fabricate a substrate ready for resist deposition and patterning. Of course, other configurations of integrated processing system 1000 are possible.

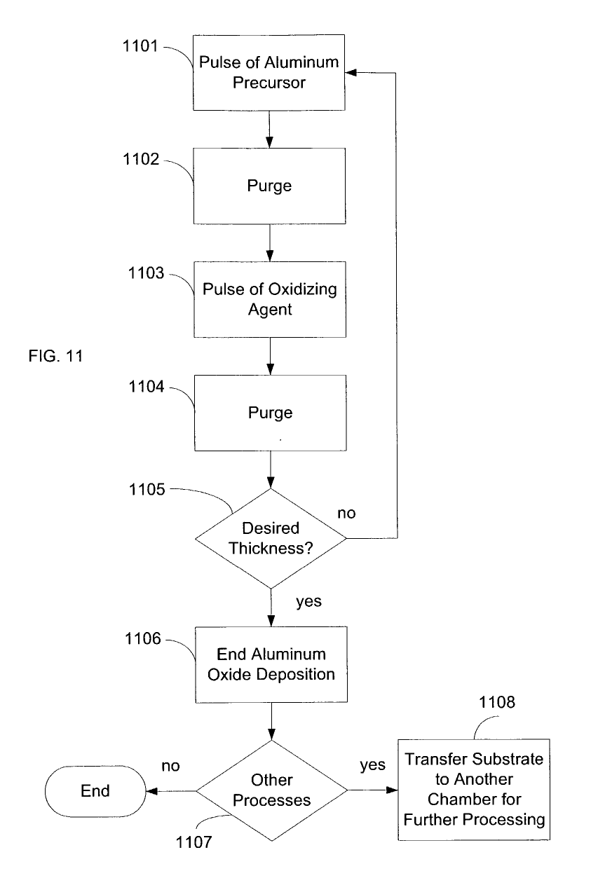

FIG. 11 is a flow chart depicting various embodiments of a method for depositing an aluminum oxide layer by cyclical layer deposition onto a substrate in a processing chamber, such processing chamber 10 described above in reference to FIGS. 1-9. The method generally begins with positioning a substrate on a substrate support member in the chamber. With the substrate positioned on the substrate support member, in step 1101, the aluminum oxide deposition process begins with the introduction of an aluminum precursor, such as trimethylaluminum, through the lid assembly into the chamber proximate the substrate surface. Other aluminum precursors may also be used such as dimethylaluminumhydride, triisopropoxyaluminum, other aluminum precursors of the formula Al(R₁)(R₂)(R₃) in which R₁, R₂, R₃ are the same or different ligands, and other suitable aluminum precursors. Once the aluminum precursor is introduced into the chamber 10, the method continues to a purge step 1102, where a purge gas is introduced through the lid assembly into the chamber as a pulse or is continuously flowed in which the pulses of the precursors are dosed therein. Examples of purge gases which may be used include, but are not limited to, helium (He), argon (Ar), nitrogen (N₂), hydrogen (H₂), and mixtures thereof. Then in step 1103, an oxidizing agent, such as ozone or oxygen species, is introduced through the lid assembly into the chamber. Other oxidizing agents may also be used, such as H₂O, N₂O, NO and other suitable oxidizing agents. The oxidizing agent is generally introduced into the chamber in a manner that directs the oxidizing agent toward the surface of the substrate, and as such, the oxidizing agent reacts with the aluminum precursor to facilitate the formation of an aluminum oxide layer on the substrate.

Once the oxidizing agent has been introduced through the lid assembly into the chamber, the method continues to step 1104, where another purge gas may be introduced into the chamber as a pulse or is continuously flowed in which the pulses of the precursors are dosed therein. The deposition cycle can continue back to the aluminum precursor pulse if it is determined at step 1105 that additional film thickness is desired. The aluminum oxide deposition cycle can be terminated if the desired film thickness is deposited as indicated at step 1106. If additional films are to be deposited as determined at step 1107, the substrate begins undergoing such processing at step 1108. The method of depositing aluminum oxide has been depicted as starting with a pulse of an aluminum precursor. In other embodiments, the aluminum oxide deposition may begin with a pulse of an oxidizing agent.

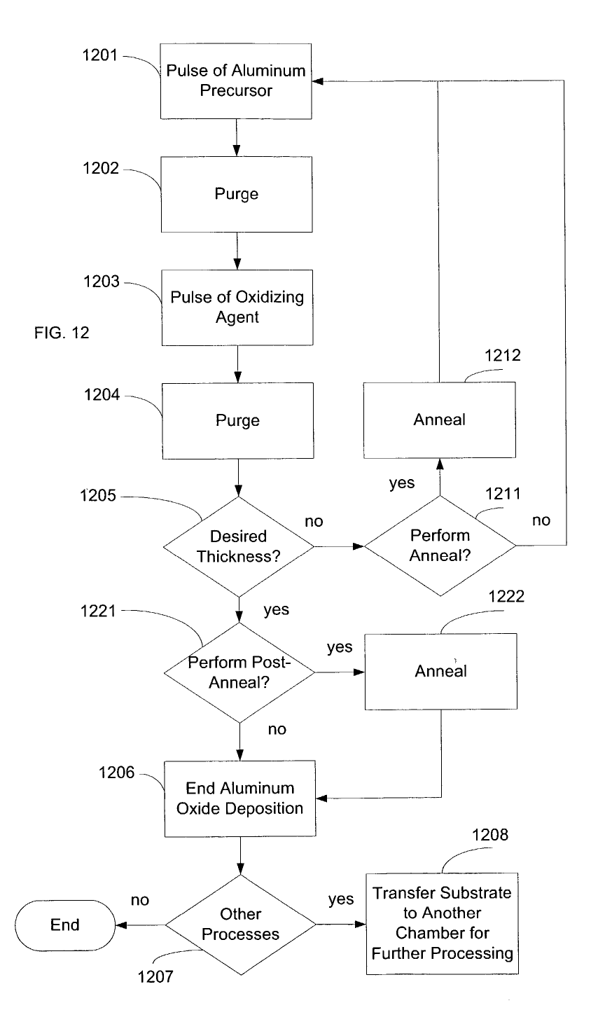

FIG. 12 is a flow chart depicting various embodiments of a method for annealing sequences performed at various times during the aluminum oxide deposition cycle in a processing chamber, such as processing chamber 10 described above in reference to FIGS. 1-9. In step 1201, a pulse of an aluminum precursor is introduced through the lid assembly into the chamber proximate the substrate surface. In step 1202, a purge gas is introduced through the lid assembly into the chamber as a pulse or is continuously flowed in which the pulses of the precursors are dosed therein. In step 1203, an oxidizing agent is introduced through the lid assembly into the chamber. In step 1204, a purge gas is introduced through the lid assembly into the chamber as a pulse or is continuously flowed in which the pulses of the precursors are dosed therein. If a desired thickness of the aluminum oxide layer has not been reached, an anneal step 1212 may be performed. Then, the cycle of pulses of aluminum precursor and oxidizing agent continues in steps 1201-1204. As a consequence, an annealing step may be performed after every deposition cycle, or after any number of cycles are performed. As an example, an annealing step may be performed every third cycle, every four cycle, etc. or at a midpoint during the deposition process. After a desired thickness of an aluminum oxide layer has been reached, a post-anneal 1222 may be performed. If other processes are to be performed, then the substrate may be transferred to other processing chambers.

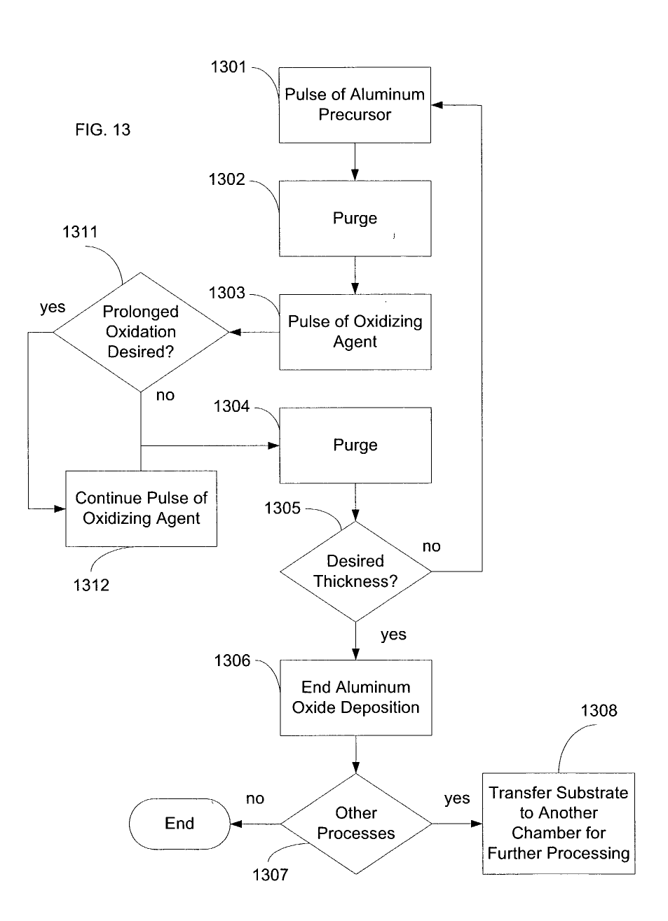

FIG. 13 is a flow diagram depicting various embodiments of a method for additional oxidizing sequences which may be performed at various times during the aluminum oxide deposition cycle in a processing chamber, such as processing chamber 10 as described above in reference to FIGS. 1-9. In step 1301, a pulse of an aluminum precursor is introduced through the lid assembly into the chamber proximate the substrate surface. In step 1302, a purge gas is introduced through the lid assembly into the chamber as a pulse or is continuously flowed in which the pulses of the precursors are dosed therein. In step 1303, an oxidizing agent is introduced through the lid assembly into the chamber. If a prolonged oxidation is desired, then the oxidizing agent continues into the chamber in step 1312. Then in step 1304, a purge gas is introduced through the lid assembly into the chamber as a pulse or is continuously flowed in which the pulses of the precursors are dosed therein. If a desired thickness of the aluminum oxide layer has not been reached, the cycle of pulses of aluminum precursor and oxidizing agent continues. The additional oxidizing sequence 1312 may be performed during every deposition cycle, or during any number of deposition cycles. As an example, the additional oxidizing sequence 1312 may be performed during every cycle, every third cycle, every fourth cycle, etc. or at the midpoint during the deposition process. In other embodiments, the prolonged oxidation process may also be used as a pre-treatment step or a post-treatment step in situ.

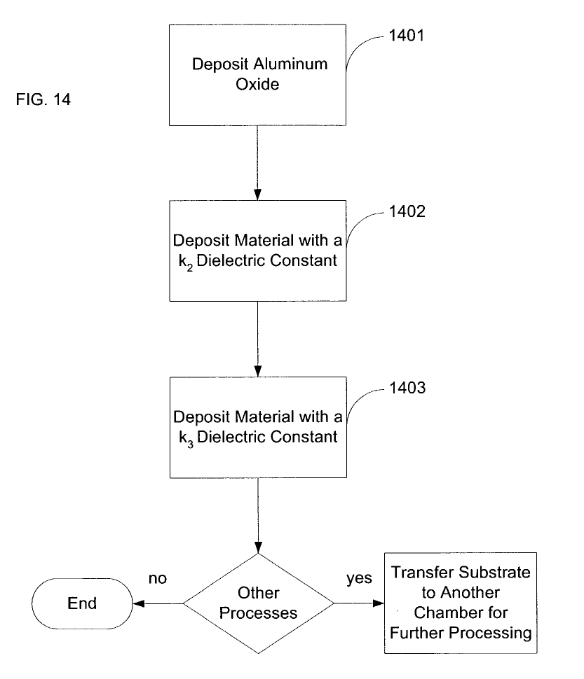

FIG. 14 is a flow diagram depicting an integrated deposition sequence of a controllable, variable dielectric constant laminate which may be performed in an integrated process system, such as processing system 1000 described in reference to FIG. 10. In step 1401, an aluminum oxide layer is first deposited. In step 1402, a second layer having a dielectric constant k₂ is deposited thereover. In step 1403, a third layer having a dielectric constant k₃ is deposited over the second dielectric constant layer. Between each step an anneal step can be performed as necessary to form a film having a desired composition and dielectric constant. In one embodiment, the sequence is preceded by a preclean and/or pretreatment process prior to deposition of materials, e.g., the aluminum oxide deposition. In performing the overall process sequence, aluminum oxide may be deposited using multiple cycles until a desired thickness is reached.

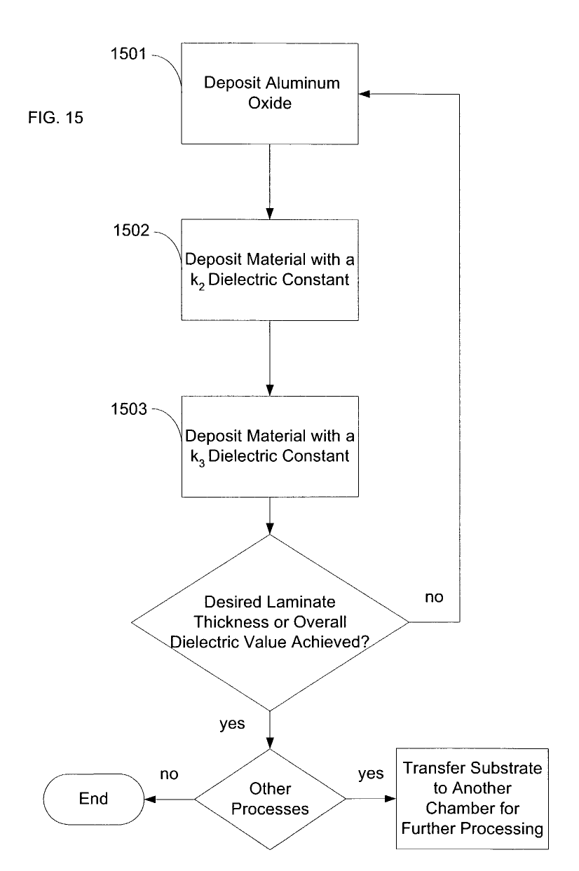

FIG. 15 is a flow diagram depicting another embodiment of an integrated sequence to form a controllable, variable dielectric constant laminate which may be performed in an integrated process system, such as processing system 1000 described in reference to FIG. 10. In step 1501, an aluminum oxide layer is first deposited. In step 1502, a second layer having a dielectric constant k₂ is deposited thereover. In step 1503, a third layer having a dielectric constant k₃ is deposited over the second dielectric constant layer. If a desired thickness of the laminate is achieved in a single cycle deposition, the process may be ended. However, if a desired thickness of the laminate is not achieved, then another deposition cycle of each of the layers may be subsequently performed over the first stack of layers. The deposition cycle of each layer may proceed until a desired thickness is formed. Following formation of the desired laminate film, the substrate can be exposed to additional processing.

The aluminum oxide deposition sequences as described in reference to FIGS. 11-15 may be followed by formation of materials thereover. For example, a metal, such as titanium, titanium nitride, tantalum, Ta nitride, tungsten, tungsten nitride, and other refractory metals or other suitable electrode materials may be deposited over the aluminum oxide layer or variable dielectric constant laminate layer. In addition, polysilicon, high dielectric constant materials, ferromagnetic materials, oxides, doped and undoped glass (USG, GPSG, PSG, PSG, etc.), carbon doped oxide films, silicon carbide, dielectric anti-reflective coatings, other films to prepare the structure for resistant deposition or patterning may be deposited, and other materials may be formed over the aluminum oxide layer or variable dielectric constant laminate layer.

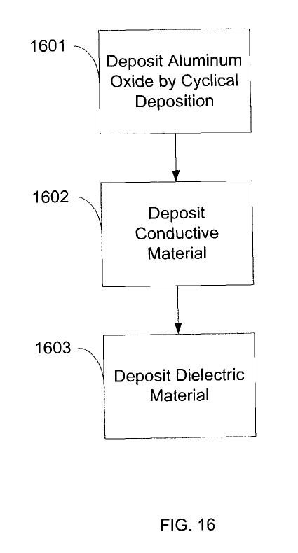

FIG. 16 is a flow diagram depicting one example of an integrated process sequence for depositing dielectric and conductive materials which may be performed in an integrated process system, such as processing system 1000 described in reference to FIG. 10. In step 1601, an aluminum oxide film is deposited using a cyclical deposition process, such as the aluminum oxide deposition processes as described in reference to FIGS. 11-15. In step 1602, a metal top electrode is then formed thereover. In step 1603, a dielectric material, such as silicon oxide or a DARC layer, is then deposited on the top metal electrode. Following this sequence, the substrate is ready for resist deposition and patterning.

FIG. 17 is a diagram depicting one example of the control signals for delivering compounds in an aluminum oxide cyclical layer deposition method utilizing a process chamber having a dual exhaust system, such as processing chamber 10 as described above in reference to FIGS. 1-9. An aluminum precursor source 1702, such as a valve disposed on the fluid injection assembly 30 as described above in reference to FIGS. 7 and 8, provides a pulse 1704 of an aluminum precursor into the chamber. An aluminum precursor exhaust 1706, such as pump system 18A of FIG. 1, is in fluid communication with the chamber for a time period 1708. In general, the time period 1708 is longer than the duration of pulse 1704 of the aluminum precursor to ensure removal of the aluminum precursor from the chamber into the aluminum precursor exhaust 1706. An oxidizing agent source 1712, such as a valve disposed on the fluid injection assembly 30 as described above in reference to FIGS. 7 and 8, provides a pulse 1714 of an oxidizing agent. An oxidizing agent exhaust 1716, such as pump system 18A of FIG. 1, is in fluid communication with the chamber for a time period 1718. In general, the time period 1718 is longer than the duration of pulse 1714 of the oxidizing agent to ensure removal of the oxidizing agent from the chamber into the oxidizing agent exhaust 1716. In one aspect, utilizing separate exhausts for the aluminum precursor and the oxidizing agent reduces the likelihood of formation of particles within the pump system, and, therefore, extends the operating life of the pump system. In the figure, the time period 1708 of the aluminum precursor exhaust 1706 and the time period 1718 of the oxidizing agent exhaust 1716 in which the exhausts are open to the chamber are shown as overlapping. In other embodiments, the time periods in which the dual exhaust are open to the chamber do not overlap.

FIG. 18 is a diagram depicting one example of the control signals for delivering compounds in an aluminum oxide cyclical layer deposition method utilizing a process chamber having a dual exhaust system and a diverter, such as processing chamber 10 as described above in reference to FIGS. 1-9. An aluminum precursor source 1802, such as a valve disposed on the fluid injection assembly 30 as described above in reference to FIGS. 7 and 8, provides a pulse 1804 of an aluminum precursor into the chamber. An aluminum precursor exhaust 1806, such as pump system 18A of FIG. 1, is in fluid communication with the chamber for a time period 1808. In general, the time period 1808 is longer than the duration of pulse 1804 of the aluminum precursor to ensure removal of the aluminum precursor from the chamber into the aluminum precursor exhaust 1806. An oxidizing agent source 1812, such as gas cabinet 2250 as described above in reference to FIGS. 9, provides a continuous flow 1814 of an oxidizing agent. A diverter 1822, such as diverter 2290 of FIG. 9, diverts the oxidizing agent to the chamber for a time period 1824 and diverts the oxidizing agent to the foreline of the oxidizing agent exhaust 1816 for a time period 1826. An oxidizing agent exhaust 1816, such as pump system 18A of FIG. 1, is in fluid communication with the chamber for a time period 1818. In general, the time period 1818 is longer than the duration of the time period 1824 in which the oxidizing agent is diverted to the chamber to ensure removal of the oxidizing agent from the chamber into the oxidizing agent exhaust 1716. In one aspect, utilizing separate exhausts for the aluminum precursor and the oxidizing agent reduces the likelihood of formation of particles within the pump system, and, therefore, extends the operating life of the pump system. In another aspect, the diverter reduces pressure variations of the oxidizing agent exhaust 1816. In the figure, the time period 1808 of the aluminum precursor exhaust 1806 and the time period 1818 of the oxidizing agent exhaust 1816 in which the exhausts are open to the chamber are shown as overlapping. In other embodiments, the time periods in which the dual exhaust are open to the chamber do not overlap.

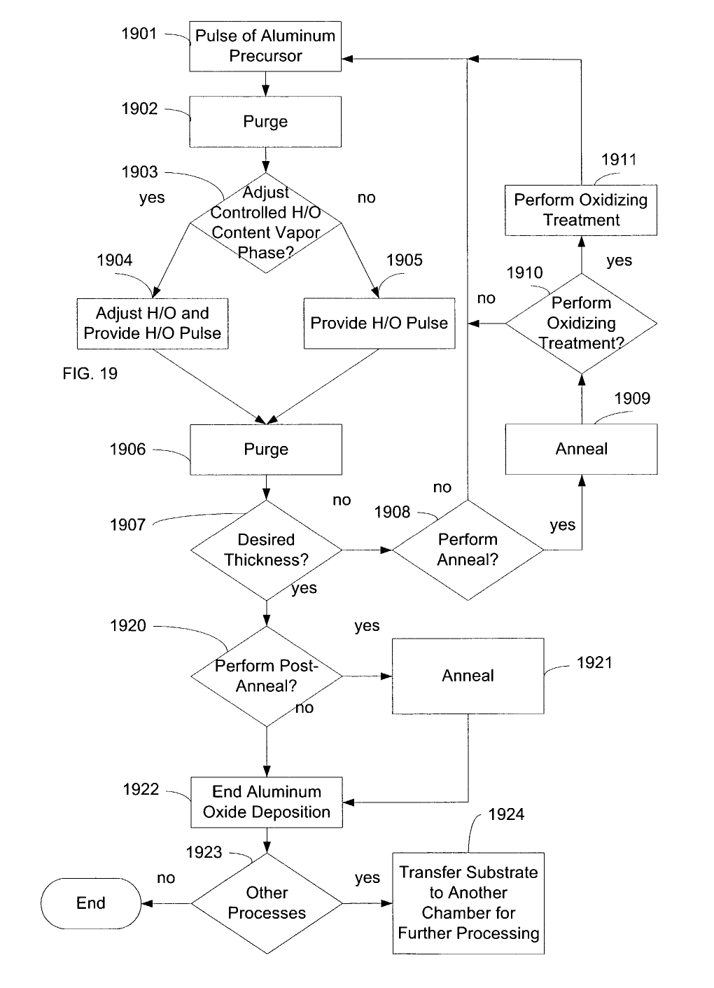

FIG. 19 is a flow chart depicting various embodiments of a deposition of aluminum oxide (AlₓO_{y}) using controllable/variable hydrogen/oxygen content water vapor with variable/selectable annealing and oxidizing sequences which may be performed in a single chamber or in a plurality of chambers. One example of a chamber adapted to provide a controllable/variable hydrogen/oxygen content water vapor is a rapid thermal heating apparatus, such as but not limited to, the Radiance Centura, available from Applied Materials, Inc. of Santa Clara, Calif. One embodiment of a rapid thermal heating apparatus is disclosed in U.S. Pat. No. 6,037,273, entitled “Method and Apparatus for lnsitu Vapor Generation,” assigned to Applied Materials, Inc. of Santa Clara, Calif., which is a Continuation-In-Part Application to U.S. patent application Ser. No. 08/893,774, both of which are incorporated by reference in their entirety to the extent not inconsistent with the present disclosure.

In step 1901, a pulse of an aluminum precursor is introduced through the lid assembly into the chamber proximate the substrate surface. In step 1902, a purge gas is introduced through the lid assembly into the chamber as a pulse or is continuously flowed in which the pulses of the precursors are dosed therein. In step 1904 or in step 1905, a pulse of a hydrogen/oxygen content vapor provided to the substrate surface. The relative amounts of hydrogen and oxygen in the vapor may be adjusted during cycling or may remain at a fixed level. Generally, the vapor concentrations run into oxygen rich vapors comprising mostly oxygen and hydrogen rich vapors comprising mostly hydrogen. Either or both types of vapors may be used during a given cycle. In step 1906, a purge gas is introduced through the lid assembly into the chamber as a pulse or is continuously flowed in which the pulses of the precursors are dosed therein. The deposition cycle can continue back to the aluminum precursor pulse 1901 if it is determined at step 1907 that additional film thickness is desired or can be terminated if the desired film thickness is deposited as indicated at step 1922. An annealing step 1910 and/or an oxidizing treatment 1911 may be performed after every deposition cycle, or after any number of cycles are performed.

In accordance with another embodiment, the annealing step is followed by an oxidizing treatment. It is to be appreciated that the oxidizing treatment may be performed in a separate chamber or in the annealing chamber. If the oxidizing treatment is to be conducted in the same chamber as the anneal, then after the annealing step, the annealing ambient is changed to the oxidizing ambient to conduct the oxidizing process. Additionally, such treatments may be used to ensure complete oxidation of the layer as well as to compensate for a layer formation deficient of oxygen.

It is to be appreciated that the actual cycle times, pulse times of precursors, pulse times of oxidizing agents, purge times, anneal times, oxidizing treatments, and/or evacuation times of the method as described above in reference to FIGS. 11-19 may vary between cycles or remain constant during a pre-determined number of cycles. In addition, one or more of the methods as described in reference to FIGS. 11-19 may be combined.

Although the invention has been described in terms of specific embodiments, one skilled in the art will recognize that various modifications may be made that are within the scope of the present invention. The scope of the invention should not be based upon the foregoing description. Rather, the scope of the invention should be determined based upon the claims recited herein, including the full scope of equivalents thereof.

What is claimed is:

1. A substrate processing chamber, comprising:
a chamber body;
a substrate support having a substrate receiving surface disposed in the chamber body;
a lid disposed on the chamber body;
an injection plate mounted on the lid and having a recess, and a bottom surface of the recess having a plurality of apertures, the apertures limited to an area proximate a central portion of the substrate receiving surface.

2. The substrate processing chamber of claim 1, further comprising one or more inlet passages formed through the lid in fluid communication with the recess of the injection plate.

3. The substrate processing chamber of claim 2, wherein a fluid flow path is defined through the inlet passages of the lid, through the recess of the injection plate, and through the apertures of the recess of the injection plate.

4. The substrate processing chamber of claim 1, wherein the injection plate includes one or more bosses maintaining a spaced-apart relation between the injection plate and the lid.

5. The substrate processing chamber of claim 1, further comprising a fluid injection system coupled to the lid and in fluid communication with the one or more inlet passages.

6. A substrate processing chamber, comprising:
a chamber body having interior sidewalls and an interior bottom wall;
a top liner disposed along the interior sidewalls of the chamber body;
a bottom liner disposed on the interior bottom wall of the chamber body;
a gap defined between the top liner and the bottom liner to allow a purge gas to be introduced therethrough.

7. The substrate processing chamber of claim 6, wherein the bottom liner includes a plurality of ledges adapted to support the top liner thereon.

8. The substrate processing system of claim 7, wherein the top liner further comprises one or more fingers for aligning with one or more of the ledges of the bottom liner.

9. The substrate processing chamber of claim 6, wherein a channel is formed along the interior bottom wall of the chamber body in fluid communication with the gap between the top liner and the bottom liner.

10. The substrate processing system of claim 9, further comprising a purge gas inlet formed at the interior bottom wall in fluid communication with the channel.

11. A substrate processing chamber, comprising:
a chamber body and a lid assembly defining an interior cavity; and
two or more exhausts selectively coupled to the interior cavity.

12. The substrate processing chamber of claim 11, further comprising a fluid injection system coupled to the lid assembly, the fluid injection system comprising two or more valves.

13. The substrate processing chamber of claim 12, wherein the two or more exhausts are synchronized with the two or more valves.

14. The substrate processing chamber of claim 11, further comprising at least one diverter to couple at least one gas source selectively between the interior cavity and between at least one of the exhausts.

15. The substrate processing chamber of claim 11, wherein the two or more exhausts are synchronized with the at least one diverter.

16. A method for forming aluminum oxide over a substrate, comprising:
providing one or more cycles of gases to a region adjacent a substrate surface, each cycle comprising:
separately providing a pulse of an aluminum precursor and a pulse of an oxidizing agent to a region adjacent a substrate surface; and
providing a purge gas to the region adjacent the substrate surface between the pulse of the aluminum precursor and the pulse of the oxidizing agent.

17. The method of claim 16, further comprising performing an in-situ anneal substrate after a selected number of cycles.

18. The method of claim 16, wherein selected pulses of the oxidizing agent are provided for a prolonged time period.

19. The method of claim 16, further comprising forming one or more additional dielectric material layers over the aluminum oxide layer.

20. The method of claim 16, wherein the oxidizing agent is a controllable hydrogen and oxygen content water vapor.
